(19) United States
(12) Patent Application Publication
(10) Pub. No.: US 2007/0278630 A1
(43) Pub. Date: Dec. 6, 2007

(54) Heat sink dissipating device for electrical connector

(75) Inventor: Wayne Hsieh, Tu-Cheng (TW)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND.CO., LTD.

(21) Appl. No.: 11/810,338

(22) Filed: Jun. 5, 2007

(30) Foreign Application Priority Data
Jun. 5, 2006 (TW) 95209734

(51) Int. Cl. H01L 23/495

(52) U.S. Cl. 257/675

(57) ABSTRACT

A heat sink dissipating device (1) includes a heat sink assembly (20), a first attachment frame (100) and a second attachment frame (110). The first attachment frame defines a region (113) for the heat sink assembly to be retained thereon. The second attachment frame includes a plurality frame pieces (101) to be engaged on the first attachment frame and configured for surrounding a peripheral portion of the heat sink assembly. A heat dissipating recess (102) extends transversely of at least one frame piece towards the peripheral portion of the heat sink assembly so as to allow heat air to be dissipated from the heat sink assembly through the heat dissipating recess. As such, the inclusion of the air flowing opening of the mating frame piece can provide heat dissipation in a lateral direction from the peripheral portion of the heat sink assembly.

### BACKGROUND OF THE INVENTION

1. Field of the Invention

The present invention relates to the art of electrical connectors, and more particularly to a heat sink dissipating device for use in an electrical connector for providing effective heat dissipation of a heat sink assembly mounted onto the electrical connector.

2. Description of the Related Art

One conventional heat sink dissipating device 1′ is shown in FIGS. 3 and 4. The heat sink dissipating device 1′ comprises an upper attachment frame 100′, a lower attachment frame 110′, and a heat sink assembly 20′ sandwiched between the upper attachment frame 100′ and the lower attachment frame 110′. The lower attachment frame 110′ defines a first engagement surface region 113′ located peripheral to the lower attachment frame 110′ for the upper attachment frame 100′ to be engaged thereon, and a second engagement surface region 115′ recessed with respect to the first engagement surface region 113′ and located at a middle portion of the lower attachment frame 110′ for engagement with a bottom surface of the heat sink assembly 20′ so as to accommodate a lower portion of the heat sink assembly 20′ within the second engagement surface region 115′. An upper portion of the heat sink assembly 20′ is exposed beyond the first engagement surface region 113′. Due to having the upper attachment frame 100′ engaged onto the first engagement surface region 113′ of the lower attachment frame 110′, heat from the heat sink assembly 20′ is apt to be dissipated in a single upward direction from the middle location of the lower attachment frame 110′, which is defined as the second engagement surface region 115′ for accommodating the heat sink assembly 20′, not dissipated in a lateral or transverse direction from a peripheral location, such as the first engagement surface region 113′. For most instances, this configuration of the heat sink dissipating device 1′ cannot provide effective heat dissipation for the heat sink assembly 20′, which is to be mounted onto an electrical connector (not shown).

### SUMMARY OF THE INVENTION

A heat sink dissipating device according to one embodiment of the present invention includes a heat sink assembly, a first attachment frame and a second attachment frame. The first attachment frame defines a region for the heat sink assembly to be retained thereon. The second attachment frame includes a plurality frame pieces to be engaged on the first attachment frame and configured for surrounding a peripheral portion of the heat sink assembly. A heat dissipating recess extends transversely of at least one frame piece towards the peripheral portion of the heat sink assembly so as to allow heat air to be dissipated from the heat sink assembly through the heat dissipating recess. As such, the inclusion of the air flowing opening of the at least one mating frame piece can provide heat dissipation in a lateral direction from the peripheral portion of the heat sink assembly, thereby achieving an effective heat dissipation in both of the lateral direction, and the upward direction as known in the prior art.

Other features and advantages of the present invention will become more apparent to those skilled in the art upon examination of the following drawings and detailed description of preferred embodiments, in which:

### BRIEF DESCRIPTION OF THE DRAWINGS

FIG. 1 is an exploded, perspective view of a heat sink dissipating device according to a preferred embodiment of the present invention;

FIG. 2 is an assembled, perspective view of the heat sink dissipating device of FIG. 1;

FIG. 3 is an exploded, perspective view of a conventional heat sink dissipating device; and

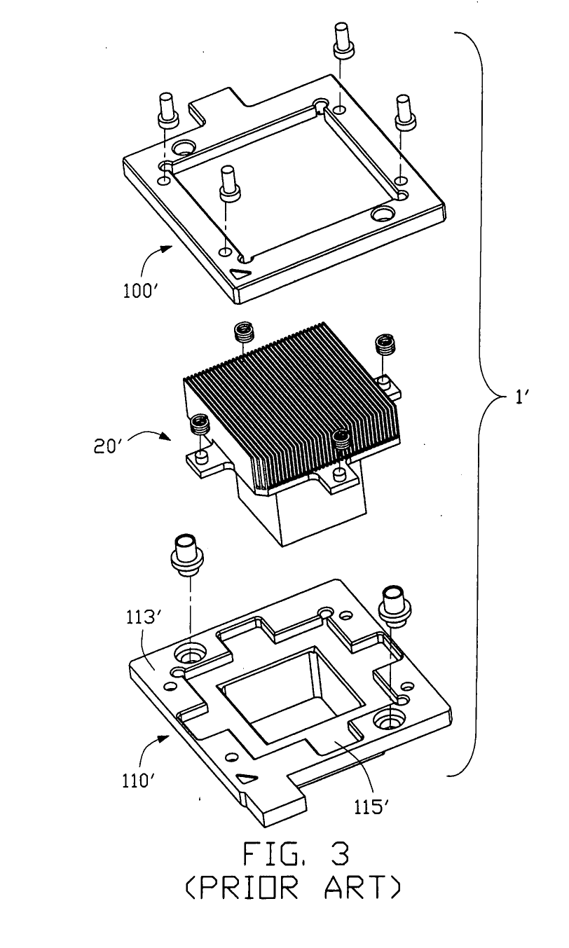

FIG. 4 is an assembled, perspective view of the conventional heat sink dissipating device of FIG. 3.

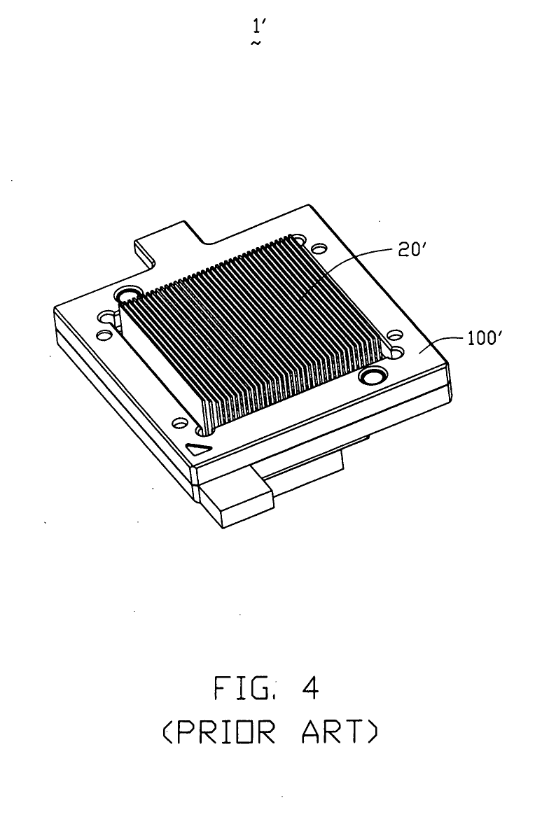

### DETAILED DESCRIPTION OF PREFERRED EMBODIMENT

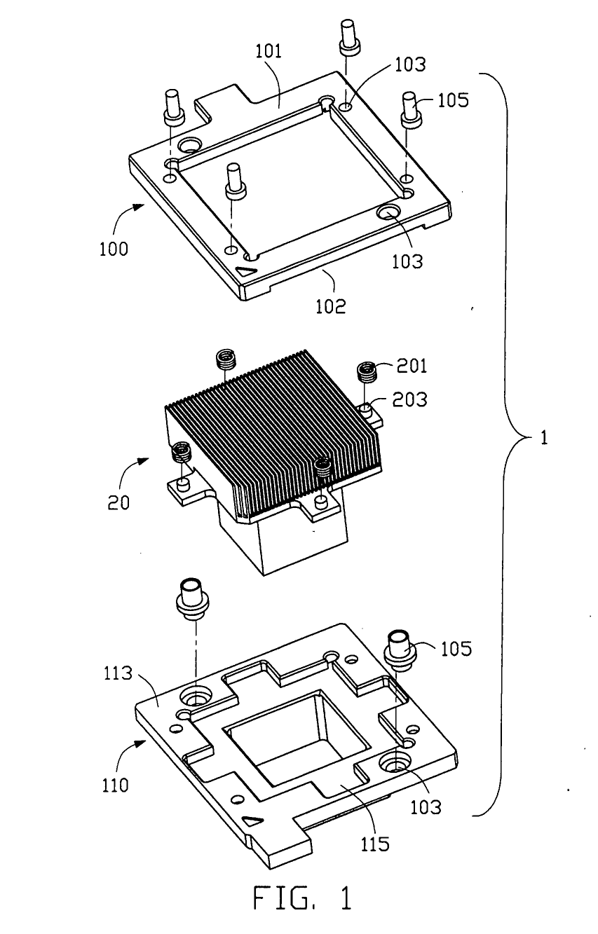

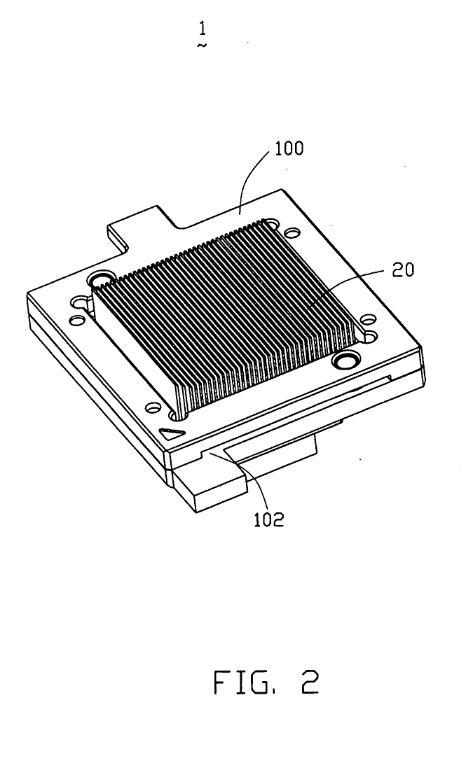

Referring to FIGS. 1 and 2, a heat sink dissipating device 1 according to the preferred embodiment of the present invention comprises an upper attachment frame 100, a lower attachment frame 110, and a heat sink assembly 20 sandwiched between the upper attachment frame 100 and the lower attachment frame 110. The lower attachment frame 110 defines a region for the heat sink assembly 20 to be retained thereon. The upper attachment frame 100 includes a plurality of mating frame pieces 101 to be engaged on the lower attachment frame 110 and configured for surrounding a peripheral portion of the heat sink assembly 20.

In this embodiment, the lower attachment frame 110 defines a first engagement surface region 113 for the mating frame pieces, such as a four-sided frame or a substantially rectangular frame, to be engaged thereon, and a second engagement surface region 115 recessed with respect to the first engagement surface region 113 and located at a middle portion of the lower attachment frame 110. The second recessed engagement surface region 115 preferably has a substantially cruciform shape, from a top view, such that a lower portion or a bottom surface portion of the heat sink assembly 20 engages onto the second engagement surface region 115 so as to be accommodated within the lower attachment frame 110, and an upper portion of the heat sink assembly 20 extends at least beyond the first engagement surface region 113. In this embodiment, an air flowing opening or recess 102 extends transversely of one of the mating frame pieces 101 towards the peripheral portion or upper portion of the heat sink assembly 20 for allowing heat air to be dissipated in a lateral direction from at least the upper peripheral portion of the sink assembly 20 through the opening 102 of the mating frame piece 101. However, in other embodiments, the air flowing opening 102 may be defined on each side of four frame pieces 101 depending on various applications.

Further, a plurality of mounting points, such as holes 103 of different shapes and/or dimensions, are defined between the upper and lower attachment frames 100, 110 for fastening means, such as pin-like elements 105, to be inserted therein so as to mount the heat sink assembly 20 between the upper attachment frame 100 and the lower attachment frame 110. In addition, a plurality of spring elements 201 are disposed between the upper attachment frame 100 and the heat sink assembly 20 so that the heat sink assembly 20 is elastically sandwiched between the upper and lower attachment frames 100, 110 for shock absorbing consideration when external force is improperly exerted on the heat sink dissipating device 1.

Referring to FIGS. 1 and 2, in assembly, the heat sink assembly 20 is preloaded into the second engagement surface region 115 of the lower attachment frame 110 with the plurality of spring elements 201 disposed onto four side tabs 203 of the heat sink assembly 20. The upper attachment frame 100 is then assembled onto the heat sink assembly 20 to have its mating frame pieces 101 engageable onto the first engagement surface region 113 of the lower attachment frame 110. The pin-like elements 105 are insertable into the mounting holes 103 of the upper and lower attachment frame 100, 110 to hold the heat sink assembly 20 between the upper and lower attachment frame 100, 110. As compared with the prior art, the inclusion of the air flowing opening 102 of one mating frame piece 101 or openings 102 of one or more mating frame pieces 101 can provide heat dissipation in a lateral direction from the upper peripheral portion of the heat sink assembly 20, thereby achieving an effective heat dissipation in both of the lateral direction, and the upward direction as known in the prior art.

While the present invention has been described with reference to preferred embodiments, the description of the invention is illustrative and is not to be construed as limiting the invention. Various of modifications to the present invention can be made to preferred embodiments by those skilled in the art without departing from the true spirit and scope of the invention as defined by the appended claims.

What is claimed is:

1. A heat sink dissipating device comprising:
an upper attachment frame and a lower attachment frame; and
a heat sink assembly sandwiched between the upper attachment frame and the lower attachment frame;
the lower attachment frame defining a first engagement surface region for a mating portion of the upper attachment frame to be engaged thereon and a second engagement surface region recessed with respect to the first engagement surface region such that a lower portion of the heat sink assembly engages onto the second engagement surface region, an upper portion of the heat sink assembly extending at least beyond the first engagement surface region of the lower attachment frame; and
an air flowing opening extending transversely of the mating portion towards the upper portion of the heat sink assembly for allowing hot air to be dissipated from the heat sink assembly through said air flowing opening of the mating portion.

2. The heat sink dissipating device as recited in claim 1, wherein the mating portion of the upper attachment frame is located around a periphery of the heat sink assembly to form a rectangular frame.

3. The heat sink dissipating device as recited in claim 2, wherein said air flowing opening is defined on at least one side of the rectangular frame.

4. The heat sink dissipating device as recited in claim 3, wherein said air flowing opening is defined on each side of the rectangular frame.

5. The heat sink dissipating device as recited in claim 1, wherein the second engagement surface region has a substantially cruciform shape, from a top view.

6. The heat sink dissipating device as recited in claim 1, wherein a plurality of mounting points is defined between the upper and lower attachment frames for establishing a mechanical interconnection between the upper and lower attachment frames.

7. The heat sink dissipating device as recited in claim 1, wherein the heat sink assembly is elastically sandwiched between the upper and lower attachment frames.

8. The heat sink dissipating device as recited in claim 7, further comprising a plurality of spring elements disposed between the upper attachment frame and the heat sink assembly.

9. A heat sink dissipating device comprising:
a heat sink assembly;
a first attachment frame defining a region for the heat sink assembly to be retained thereon;
a second attachment frame having a plurality frame pieces to be engaged on the first attachment frame and configured for surrounding a peripheral portion of the heat sink assembly; and
a heat dissipating recess extending transversely of at least one frame piece towards the peripheral portion of the heat sink assembly for allowing heat air to be dissipated from the heat sink assembly through said heat dissipating recess.

10. The heat sink dissipating device as recited in claim 9, wherein the region of the first attachment frame is recessed for engagement with a bottom surface portion of the heat sink assembly for retaining the heat sink assembly onto the first attachment frame.

11. The heat sink dissipating device as recited in claim 10, wherein the recessed region of the first attachment frame has a substantially cruciform shape, from a top view.

12. The heat sink dissipating device as recited in claim 9, wherein said heat dissipating recess is defined on each of the frame pieces.

13. The heat sink dissipating device as recited in claim 9, wherein the heat sink assembly is elastically sandwiched between the first and second attachment frames.

14. The heat sink dissipating device as recited in claim 13, comprising a plurality of spring elements disposed between the second attachment frame and the heat sink assembly.

15. A heat sink dissipating device comprising:
a heat sink assembly;
a lower attachment frame defining a region;
an upper attachment frame engaged on the lower attachment frame;
a heat sink assembly having a portion sandwiched retainably between the upper and lower frames and another portion extending upward through both said lower attachment frame and said upper attachment frame; and
a heat dissipating recess extending transversely through at least one of said lower and upper frames towards the heat sink assembly for allowing heat air to be dissipated from the heat sink assembly through said heat dissipating recess
